(19) United States
(12) Patent Application Publication
(10) Pub. No.: US 2009/0065893 A1
(43) Pub. Date: Mar. 12, 2009

(54) SEMICONDUCTOR DEVICES AND FABRICATION METHODS THEREOF

(75) Inventors: Chi-Huang Wu, Taoyuan (TW); Chien-Jung Yang, Taoyuan (TW)

Correspondence Address: QUINTERO LAW OFFICE, PC, 2210 MAIN STREET, SUITE 200, SANTA MONICA, CA, 90405, US

(73) Assignee: NANYA TECHNOLOGY CORPORATION, Taoyuan (TW)

(21) Appl. No.: 11/876,489

(22) Filed: Oct. 22, 2007

(30) Foreign Application Priority Data
Sep. 12, 2007 (TW) TW96134016

(51) Int. Cl. H01L 29/00; H01L 21/20

(52) U.S. Cl. 257/513; 438/442; 257/E29.001; 257/E21.09

(57) ABSTRACT

A semiconductor device and fabrication method thereof is disclosed. The method includes the steps of providing a substrate with a trench and a stacked layer thereon, performing an epitaxy process to form an epitaxial layer in the trench, conformably depositing an oxide layer on the epitaxial layer, and removing a portion of the oxide layer and the epitaxial layer on the bottom of the trench.

### BACKGROUND OF THE INVENTION

1. Field of the Invention

The present invention relates to a semiconductor device and fabrication methods thereof, and in particular relates to a memory device and fabrication methods thereof.

2. Description of the Related Art

Memory devices, such as dynamic random access memory (DRAM), for non-volatile storage of information, are currently in widespread use in a myriad of applications.

A conventional DRAM consists of a transistor and a capacitor, with electrical charges moving in or out of the capacitor during reading or writing. Typically a deep trench capacitor is used to reduce the size of a memory device. The capacitor is disposed in the deep trench bottom, the transistor is disposed at the deep trench top, and a thin dielectric layer, such as trench top oxide (TTO) layer, acting as an electrical insulating layer is disposed between the capacitor and the transistor.

With continuous shrinkage of device size (for example, channel length less than 50 nm), formation of source/drain regions by an ion implantation becomes more difficult because the trench is too narrow. Accordingly, a method capable of eliminating the described problems is desirable.

### BRIEF SUMMARY OF THE INVENTION

In view of the problems in the prior art, an embodiment discloses a fabrication method of a semiconductor device. The method comprises: providing a substrate with a stack thereon, wherein the stack and the substrate include a trench; performing an epitaxy process to form an epitaxial layer lining the trench; conformally depositing an oxide layer on the epitaxial layer; and removing portions of the oxide layer and the epitaxial layer on the bottom of the trench, exposing a portion of the substrate.

Another embodiment discloses a semiconductor device. The semiconductor device comprises: a substrate with a trench therein, wherein the trench possesses sidewalls and a bottom; an epitaxial layer lining the trench; and an oxide layer on the epitaxial layer.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1A˜1B are cross sections of an exemplary example of a fabrication method of a dynamic random assess memory.

FIG. 2A˜2E are cross sections of an embodiment of a fabrication method of a dynamic random assess memory.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

### Exemplary Example

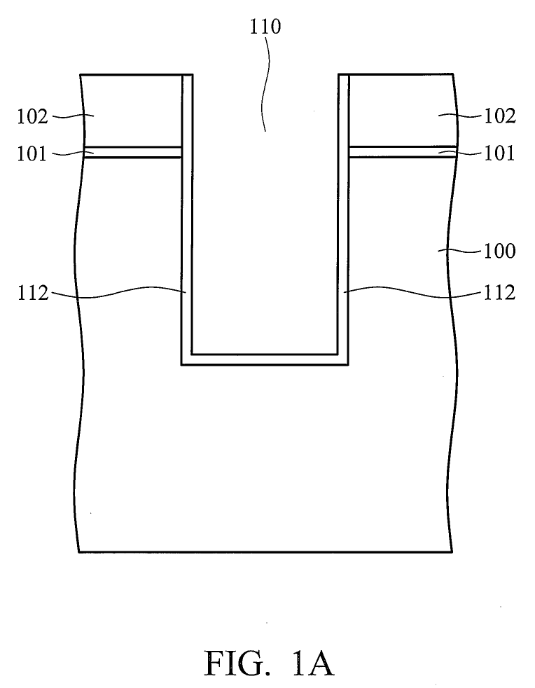

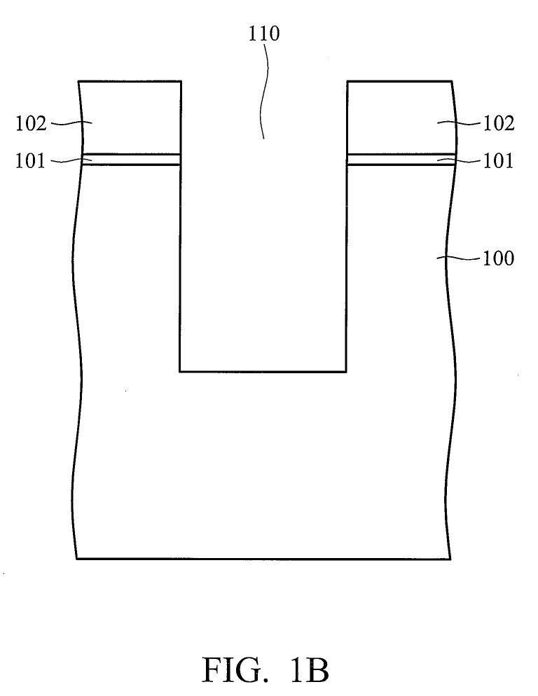

FIG. 1A˜1B are cross sections of an exemplary example of a fabrication method of a dynamic random assess memory.

Referring to FIG. 1A, a semiconductor substrate 100 such as a single crystalline silicon substrate is provided with a pad silicon oxide 101 and a pad silicon nitride 102 thereon. A deep trench 110 is formed in the semiconductor substrate 100 employing the pad silicon oxide 101 and the silicon nitride 102 as mask.

Typically, a native oxide layer 112 is formed due to exposure of the deep trench 110 in the air. Referring to FIG. 1B, the native oxide layer 112 is usually removed prior to proceedings of subsequent processes such as formation of a gate electrode.

### Embodiment

The following only includes descriptions regarding to the features of this embodiment, and well-known steps in fabricating a memory device are omitted here.

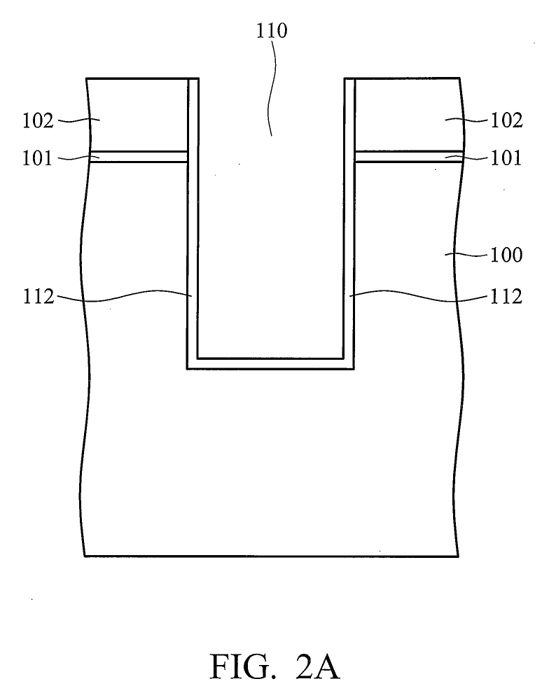

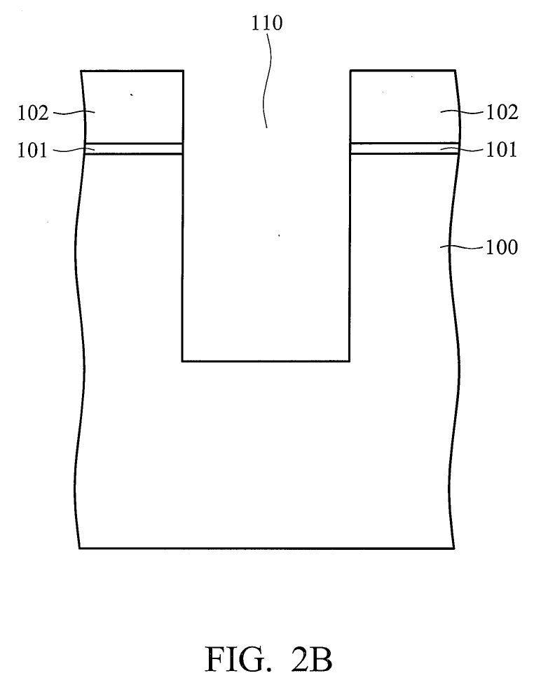

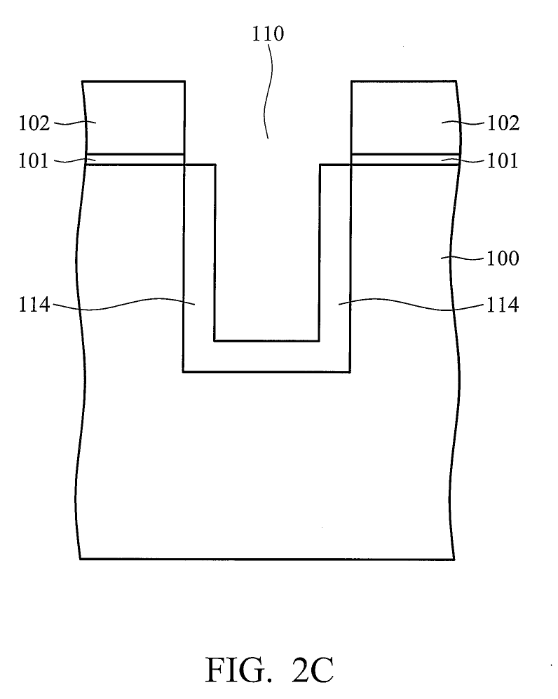

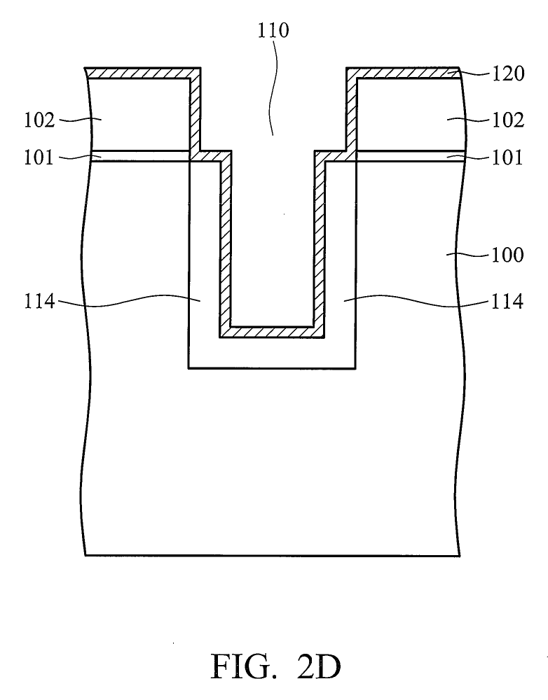

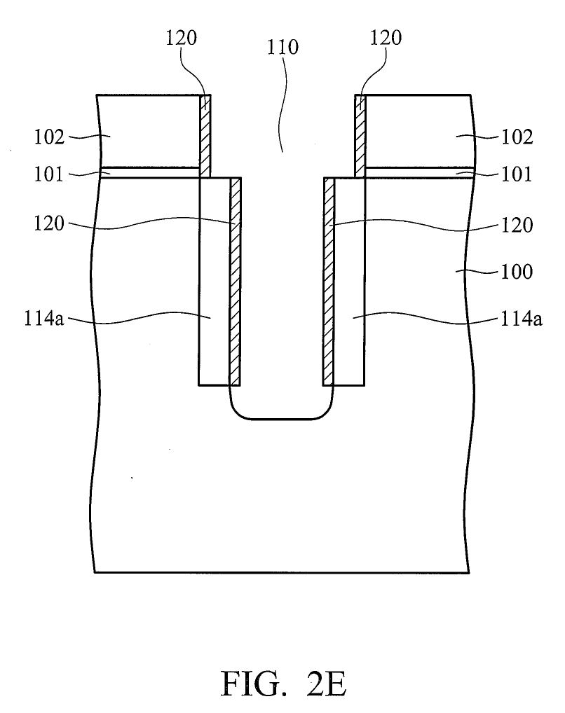

FIG. 2A˜2E are cross sections of an embodiment of a fabrication method of a dynamic random assess memory.

Referring to FIG. 2A, a semiconductor substrate 100 such as a single crystalline silicon substrate is provided with a pad silicon oxide 101 and a pad silicon nitride 102 thereon. A deep trench 110 is formed in the semiconductor substrate 100 employing the pad silicon oxide 101 and the silicon nitride 102 as mask. Formation of the pad silicon oxide 101 on the semiconductor substrate 100 can be performed utilizing furnaces; formation of pad silicon nitride 102 can be performed by a low pressure chemical vapor deposition process.

Typically, a native oxide layer 112 is formed covering sidewalls of the deep trench 110 due to exposure thereof in the air.

Referring to FIG. 2B, the native oxide layer 112 is then removed. Removal of the native oxide layer 112 includes a dry etching process, a wet etching process or a reactive ion etching process.

Referring to FIG. 2C, after removal of the native oxide layer 112, an in-situ epitaxy is performed onto the deep trench 110. That is, besides an epitaxial layer 114 is formed in the deep trench 110, the epitaxial layer 114 is also doped with suitable materials, simultaneously. The in-situ epitaxy includes a vapor phase epitaxy process or a liquid phase epitaxy process. The vapor phase epitaxy process includes a hydride vapor phase epitaxy process, a molecular beam epitaxy process, or a metalorganic chemical vapor phase epitaxy process. The described epitaxy process are omitted because they are well known.

Referring to FIG. 2D, an oxide layer 120 is deposited conformally on the silicon nitride layer 102 and epitaxial layer 114. The oxide layer 120 includes a tetraethylorthosilicate layer or a silicon oxide layer, and formation thereof includes a chemical vapor deposition process.

Referring to FIG. 2E, portions of the oxide layer 120 and the epitaxial layer 114 on the bottom of the deep trench 110 are then removed, thus exposing a portion of the substrate. This step can be performed using a dry etching process such as a reactive ion etching process. The remaining epitaxial layer 114a on the deep trench 110 serves as source and drain electrodes (or regions) of a transistor, and the space therebetween acts as a channel region. A recess cannel type transistor is obtained by proceedings of the subsequent conventional processes.

According to the described embodiment, formation of source/drain regions can be performed by a uniform ion implantation.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A fabrication method of a semiconductor device, comprising
providing a substrate with a stack thereon, wherein the stack and the substrate include a trench;
performing an epitaxy process to form an epitaxial layer lining the trench;
conformally depositing an oxide layer on the epitaxial layer; and
removing portions of the oxide layer and the epitaxial layer on the bottom of the trench, exposing a portion of the substrate.

2. The method as claimed in claim 1, wherein the epitaxy process is an in-situ epitaxy process.

3. The method as claimed in claim 1, further comprising:
removing a native oxide layer covering the sidewalls and bottom of the trench prior to the epitaxy process.

4. The method as claimed in claim 1, wherein the removal of portions of the oxide layer includes a reactive ion etching process.

5. The method as claimed in claim 1, wherein the substrate includes a P-type silicon substrate.

6. The method as claimed in claim 1, wherein the stack includes a dielectric layer.

7. The method as claimed in claim 1, wherein the stack includes a pad oxide layer and a nitride layer.

8. The method as claimed in claim 1, wherein a portion of the epitaxial layer covering sidewalls of the trench act as source and drain regions of a transistor.

9. A semiconductor device, comprising
a substrate with a trench therein, wherein the trench possesses sidewalls and a bottom;
an epitaxial layer lining the trench; and
an oxide layer on the epitaxial layer.

10. The method as claimed in claim 9, wherein the substrate includes a P-type silicon substrate.
